(19) United States
(12) Patent Application Publication
(10) Pub. No.: US 2011/0153242 A1
(43) Pub. Date: Jun. 23, 2011

(54) THERMOCOUPLE MEASUREMENT IN A CURRENT CARRYING PATH

(75) Inventors: Xiujie Gao, Troy, MI (US); Nicholas William Pinto, Ferndale, MI (US); Robert B. Gorbet, Kitchener (CA); J. Richard Culham, Waterloo (CA); Alan L. Browne, Grosse Pointe, MI (US); Nancy L. Johnson, Northville, MI (US); Huilong (William) Ma, Waterloo (CA)

(73) Assignees: GM GLOBAL TECHNOLOGY OPERATIONS, INC, Detroit, MI (US); University of Waterloo, Waterloo (CA)

(21) Appl. No.: 12/641,376

(22) Filed: Dec. 18, 2009

(51) Int. Cl. G01R 19/00; G01K 7/02; G06F 19/00

(52) U.S. Cl. 702/64; 374/179; 324/105; 702/130; 374/E07.004

(57) ABSTRACT

A method of measuring a temperature of a wire and a current flowing through the wire with a thermocouple includes taking a first voltage reading from the thermocouple with the current at a first polarity, and taking a second voltage reading from the thermocouple with the current at a second polarity. The first voltage reading is averaged with the second voltage reading to obtain an average voltage reading, which is referenced to a correlation table to calculate the temperature of the wire. Half of a voltage difference between the first voltage reading and the second voltage reading is divided by the resistance in the wire to calculate the current flowing through the wire.

### TECHNICAL FIELD

The invention generally relates to measuring a temperature and a current in a current carrying path with a thermocouple.

### BACKGROUND OF THE INVENTION

Shape Memory Alloy (SMA) devices, which typically include small diameter wires, are increasingly being incorporated into various mechanisms. The SMA devices typically change shape, i.e., elongate and/or contract, in response to a change in temperature. Often, the change in temperature is the result of passing an electrical current through the SMA device. It is important to monitor the temperature of the SMA device to ensure proper function of the SMA device.

It is known to use a thermocouple to measure the temperature of various devices. The thermocouple measures the potential difference, i.e. voltage, between two joined leads of dissimilar metallic compounds in contact with an object. The measured potential difference is referenced to a look-up/correlation table associated with the specific thermocouple used to calculate the temperature of the object. However, when a current is flowing through the object, such as an SMA device, the electromotive force flowing along the current path interferes with the potential difference reading of the thermocouple, thereby rendering the standard correlation between the potential difference measured by the thermocouple and the temperature of the object inaccurate.

### SUMMARY OF THE INVENTION

A method of using a thermocouple to calculate a temperature of a wire and a current flowing through the wire is disclosed. The thermocouple includes at least a first lead coupled to the wire and a second lead coupled to the wire, with the second lead axially spaced from the first lead a first axial distance along a longitudinal axis of the wire. The method includes measuring a first voltage reading of the thermocouple with the current at a first polarity. The method further includes measuring a second voltage reading of the thermocouple with the same current at a second polarity. The method further includes averaging the first voltage reading and the second voltage reading to obtain an average voltage reading. The method further includes calculating the temperature of the wire from the average voltage reading. The method further includes calculating a difference of the first voltage reading and the second voltage reading to obtain a voltage difference derived from the current flowing through the wire; and calculating the current flowing through the wire based upon the voltage difference between the first voltage reading and the second voltage reading.

In another aspect of the invention, a method of measuring a temperature of a wire having a current flowing through the wire with a thermocouple is disclosed. The thermocouple includes a first lead and a second lead. The method includes attaching the first lead to the wire. The method further includes attaching the second lead to the wire. The method further includes temporarily interrupting the current flowing through the wire. The method further includes measuring a first voltage reading of the thermocouple when the current is interrupted; and calculating the temperature of the wire from the first voltage reading.

In another aspect of the invention, a method of measuring a current in a wire having a current flowing through the wire with a thermocouple is disclosed. The thermocouple includes a first lead attached to the wire and a second lead attached to the wire. The second lead is axially spaced from the first lead along a longitudinal axis of the wire. The method includes measuring a voltage reading of the thermocouple. The method further includes determining a temperature of the wire. The method further includes subtracting a portion of the voltage reading of the thermocouple induced by the temperature of the wire from the voltage reading of the thermocouple to obtain a portion of the voltage reading of the thermocouple induced by the current flowing through the wire; and calculating the value of the current flowing through the wire based upon the portion of the voltage reading induced by the current flowing through the wire.

Accordingly, the invention discloses a method of measuring a temperature and/or a current flowing through the wire with a thermocouple, while the current is flowing through the wire, thereby enabling the use of the thermocouple to measure the temperature of an SMA device being heated by an electrical current.

The above features and advantages and other features and advantages of the present invention are readily apparent from the following detailed description of the best modes for carrying out the invention when taken in connection with the accompanying drawings.

### BRIEF DESCRIPTION OF THE DRAWINGS

FIG. 1 is a schematic plan view of a thermocouple attached to a wire in a first arrangement.

FIG. 2 is a schematic plan view of the thermocouple attached to the wire in a second arrangement.

FIG. 3 is a schematic plan view of an alternative thermocouple attached to the wire in a third arrangement.

### DESCRIPTION OF THE PREFERRED EMBODIMENTS

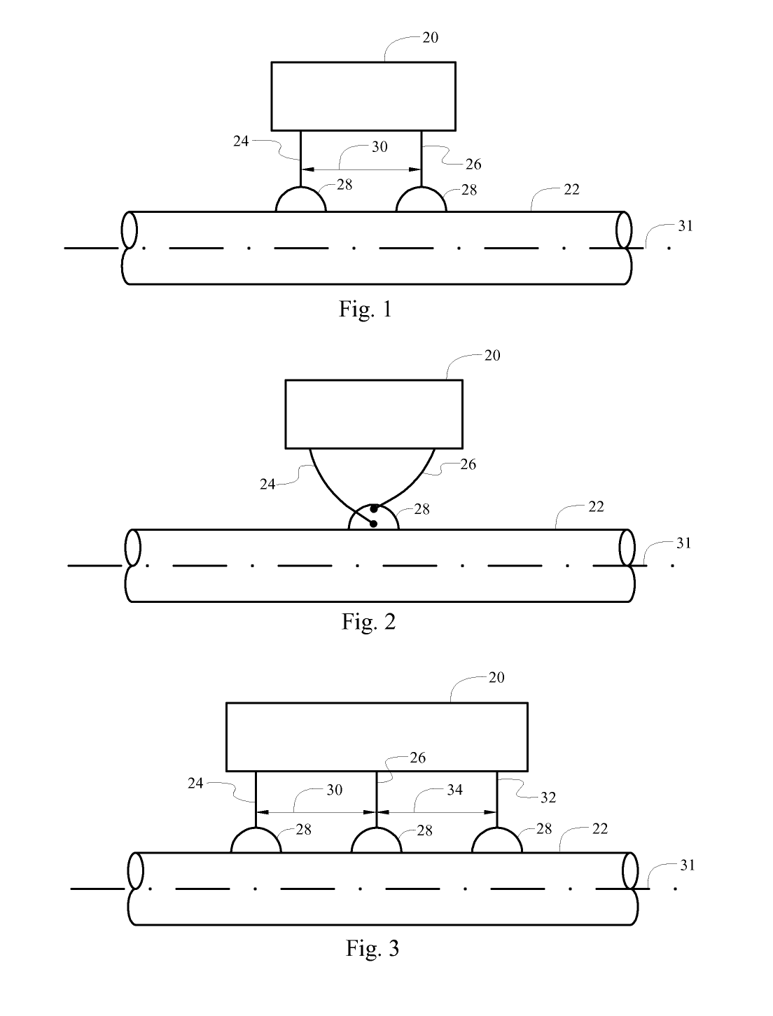

Referring to the Figures, wherein like numerals indicate corresponding parts throughout the several views, a thermocouple 20 is shown attached to a wire 22. Referring to FIG. 1, a first arrangement of the thermocouple 20 is shown. The thermocouple 20 may include any standard thermocouple 20 known in the art, and includes a first lead 24 and a second lead 26. As is known, the thermocouple 20 measures a potential difference, i.e., a voltage, between two leads manufactured from dissimilar metals. This potential difference may be correlated to a temperature, such as by reference to standardized look-up/correlation tables associated with the specific type of thermocouple 20 used. Therefore, when the two leads are attached to an object, the reading of the thermocouple 20 is related to the temperature of the object.

The wire 22 may include any type and/or size of a current carrying path having any desirable cross section, including but not limited to, a wire in spring form or a ribbon of rectangular cross section. However, the method disclosed herein is particularly suited for use with small diameter, Shape Memory Alloy (SMA) wires 22, as SMA wires 22 often carry an electrical current therethrough, preventing use of the thermocouple 20 in the standard manner.

In order to minimize the electromotive force flowing through the wire 22, an end of the first lead 24 and an end of the second lead 26 are attached to the wire 22 such that the ends of the first and second leads 24, 26 are laterally spaced from an outer circumference of the wire 22. This may be accomplished, for example, by attaching the ends of the first and second leads 24, 26 to a bead 28 formed on the outer surface of the wire 22. This may also be accomplished, for example, by first forming the bead 28 at one end of the first lead 24, and then attaching the bead 28 to the wire 22, followed by attaching the second lead 26 to the bead 28. However, it should be appreciated that the ends of the first and second leads 24, 26 may be directly attached to the wire 22, i.e., without the beads 28. Additionally, the second lead 26 may be attached to the wire 22 a first axial distance 30 from the first lead 24 along a longitudinal axis 31 of the wire 22. If the thermocouple 20 is only configured to measure the temperature of the wire 22, then the first axial distance 30 may approach and include zero, i.e., the end of the first lead 24 and the end of the second lead 26 are axially aligned along the longitudinal axis as is shown in FIG. 2. However, if the thermocouple 20 is configured to measure the current flowing through the wire 22, then the first axial distance 30 must be greater than zero, i.e., the end of the first lead 24 and the end of the second lead 26 must be axially spaced from each other as shown in FIG. 1. A larger value of the first axial distance 30 may improve accuracy of the current measurement.

The invention discloses a method of using a thermocouple 20 to calculate a temperature of the wire 22 and a current flowing through the wire 22. The calculated temperature and current of the wire 22 may be used for any suitable purpose, including but not limited to, controlling the SMA wire 22. The method includes measuring a first voltage reading of the thermocouple 20 with the current at a first polarity. Accordingly, with the current at the first polarity, the thermocouple reading measures the potential difference between the first lead 24 and the second lead 26. The potential difference includes a first portion and a second portion. The first portion of the thermocouple reading is the portion of the thermocouple reading that is induced by the temperature of the wire 22. The second portion of the thermocouple reading is the portion of the thermocouple reading that is induced by the current flowing through the wire 22.

In order to isolate the first portion of the thermocouple reading, the method further comprises reversing the polarity of the current flowing through the wire 22, i.e., changing the polarity of the current from the first polarity to a second polarity opposite the first polarity, while maintaining the same magnitude of the current. It is assumed that the temperature of the wire 22 remains constant between the first lead 24 and the second lead 26 during the polarity reversal. The method further includes measuring a second voltage reading of the thermocouple 20 with the same current at the second polarity.

The method further includes averaging the first voltage reading and the second voltage reading to obtain an average voltage reading. In other words, the first voltage reading and the second voltage reading are summed together, and the sum of the first voltage reading and the second voltage reading is divided by two to obtain the average voltage reading, i.e., the arithmetic mean between the first voltage reading and the second voltage reading. Because the first voltage reading was taken at the first polarity, and the second voltage reading was taken at the second, opposite polarity, averaging the first voltage reading and the second voltage reading cancels out the second portion of the thermocouple reading induced by the current flowing through the wire 22, leaving only the first portion of the thermocouple reading induced by the temperature of the wire 22. The method further includes calculating the temperature of the wire 22 from the average voltage reading. The average voltage reading may be correlated to a temperature through the use of an appropriate look-up/correlation table associated with the specific thermocouple used.

Alternatively, the temperature of the wire 22 may be obtained by temporarily interrupting the current flowing through the wire 22. Immediately after the current flowing through the wire 22 is interrupted, one or more voltage readings may be taken from the thermocouple 20. If multiple voltage readings are taken, then the multiple voltage readings may be averaged together to obtain the first voltage reading. The multiple voltage readings are taken within a time period immediately after interruption of the current suitable to ensure that the wire 22 has not cooled. For example, the multiple voltage readings may be taken over a period of time equal to or greater than a 1 nanosecond time period after interrupting the current. However, the time period is dependent upon the sized and geometry of the wire 22, and may be greater than or less than the 1 nanosecond time period disclosed above. As described above, the temperature of the wire 22 may be calculated by referencing the first voltage reading to the appropriate look-up/correlation table associated with the specific type of thermocouple 20 used.

Alternatively, after interrupting the current flowing through the wire 22, multiple voltage readings may be taken from the thermocouple 20 over a period of time. The period of time may be sufficient to permit some cooling of the wire 22. For example, voltage readings may be taken over a period of time equal to or less than a 1000 second period of time. However, the time period is dependent upon the size and geometry of the wire 22, and may be greater than or less than the 1000 second time period disclosed above. The multiple readings from the thermocouple 20 may be used to extrapolate the first voltage reading of the wire 22 at the point in time when the current was interrupted. The first voltage reading may be extrapolated, for example, by use of a best fit curve. As described above, the temperature of the wire 22 may be calculated by referencing the first voltage reading to the appropriate look-up/correlation table associated with the specific type of thermocouple 20 used.

The temperature may further be calculated by eliminating the second portion of the thermocouple reading induced by the current flowing through the wire 22. If the current flowing through the wire 22 is known, the voltage for the second portion of the thermocouple reading may be calculated by the use of Equations 1 and 2 below. The calculated voltage associated with the second portion of the overall thermocouple reading is then subtracted from the overall thermocouple reading, leaving only the fist portion of the thermocouple reading induced by the temperature of the wire 22. The temperature of the wire 22 may be calculated by referencing the voltage value associated with the first portion of the thermocouple reading to the appropriate look-up/correlation table associated with the specific type of thermocouple 20 used.

In order to calculate the current flowing through the wire 22, the method includes calculating a difference of the first voltage reading and the second voltage reading to obtain a voltage difference derived from the current flowing through the wire 22. In other words, the second voltage reading is subtracted from the first voltage reading to obtain the voltage difference between the first voltage reading and the second voltage reading.

The method further includes calculating the current flowing through the wire 22 based upon the voltage difference between the fist voltage reading and the second voltage reading. The current is calculated by dividing the voltage difference by two to obtain the half of the voltage difference between the first voltage reading and the second voltage reading. Calculating the half of the voltage difference between the first voltage reading and the second voltage reading cancels out the first portion of the thermocouple reading induced by the temperature of the wire 22, leaving only the second portion of the thermocouple reading induced by the current flowing through the wire 22. The half of the voltage difference is then divided by the resistance of the wire 22 along the first axial distance 30 to obtain the current.

Accordingly, calculating the current flowing through the wire 22 based upon the voltage difference described above may include solving Equation 1:

$$I = \frac{V}{R} \qquad 1 )$$

wherein: I is the current flowing through the wire 22; V is the voltage induced by the current flowing through the wire 22 over the first axial distance 30, i.e., the electromotive force due to the presence of the current; and R is the resistance of the wire 22 along the first axial distance 30.

Calculating the current flowing through the wire 22 based upon the voltage difference may further include solving Equation 2:

$$R = e [ \frac{L}{A} ] \qquad 2 )$$

wherein R is the resistance of the wire 22 along the first axial distance 30, e is a proportionality constant for the material of the wire 22, L is the axial distance between the first lead 24 and the second lead 26, and A is the cross sectional area of the wire 22. However, it should be appreciated that the current may be calculated in some other manner not specifically described herein, including but not limited to, referencing a pre-defined table correlating known currents to voltage readings.

In order to solve Equation 2, the first axial distance 30 and the cross sectional area of the wire 22 must be known. Accordingly, the method further includes measuring the first axial distance 30, and calculating the cross sectional area of the wire 22. The first axial distance 30 and the cross sectional area of the wire 22 may be measured and/or calculated in any suitable manner, including the use of any suitable measurement device.

Alternatively, the current may be calculated by subtracting the first portion of the thermocouple reading induced by the temperature of the wire 22 from the overall thermocouple reading, to obtain the second portion of the thermocouple reading induced by the current flowing through the wire 22. This alternative method of calculating the current flowing through the wire 22 includes measuring a voltage reading of the thermocouple 20, determining the temperature of the wire 22, calculating the portion of the voltage reading induced by the temperature of the wire 22, i.e., the first portion of the thermocouple reading, and subtracting the voltage induced by the temperature of the wire 22 from the measured voltage reading of the thermocouple 20. The temperature of the wire 22 may be determined in any suitable manner, such as by a sensor, e.g., a thermometer, configured for sensing the temperature of the wire 22. If the sensor used to measure the temperature of the wire 22 is affected by the current flowing through the wire 22, e.g., the thermocouple 20, then the temperature of the wire 22 may be measured while temporarily interrupting the current in the wire 22. If the sensor used to measure the temperature of the wire 22 is not affected by the current flowing through the wire 22, e.g., an infrared sensor, then there is no need to interrupt the current flowing through the wire 22, and the temperature of the wire 22 may be measured while the current is flowing through the wire 22. Furthermore, if the current flowing through the wire 22 does not substantially affect the temperature of the wire 22, i.e., when I²R resistive heating is negligible as with a very low current or wire with low linear resistance, then the temperature of the wire 22 may be measured either before applying or after interrupting the current in the wire 22. The determined temperature of the wire 22 may be used to calculate a correlated voltage for the first portion of the thermocouple reading by reference to the appropriate look-up/correlation table associated with the specific thermocouple used. The method further includes subtracting the correlated voltage for the first portion of the thermocouple reading induced by the temperature of the wire 22 from the overall voltage reading of the thermocouple 20 to obtain the second portion of the voltage reading of the thermocouple 20 induced by the current flowing through the wire 22. Once the voltage reading for the second portion of the thermocouple reading is obtained, the current flowing through the wire 22 may be calculated in the same manner as described above, utilizing Equations 1 and 2.

Alternatively, the second portion of the thermocouple reading may be calculated by taking a thermocouple reading after interrupting the current in the wire 22, to measure the voltage induced in the wire 22 by the temperature of the wire 22, and subtracting the voltage reading taken after interrupting the current in the wire 22 from the overall voltage reading of the thermocouple 20, taken before interrupting the current in the wire 22, to obtain the second portion of the thermocouple reading.

Referring to FIG. 3, a second arrangement of the thermocouple 20 is shown. The second arrangement of the thermocouple 20 includes a three lead thermocouple 20, in which the thermocouple 20 includes a first lead 24, a second lead 26 and a third lead 32. The second arrangement of the thermocouple 20 includes two of the first lead 24, the second lead 26 and the third lead 32 each being one of a positive lead or a negative lead, and the other of the first lead 24, the second lead 26 and the third lead 32 being the other of the negative lead or the positive lead. As shown, the first lead 24 and the third lead 32 are positive leads, while the second lead 26 is a negative lead. Alternatively, the first lead 24 and the third lead 32 may be negative leads, while the second lead 26 is a positive lead. Preferably, the third lead 32 is attached to the wire 22 such that the third lead 32 is spaced axially from the second lead 26 a second axial distance 34, the second lead 26 disposed axially between the first lead 24 and the third lead 32, and the first axial distance 30 is equal to the second axial distance 34. However, it should be appreciated that the first axial distance 30 need not equal the second axial distance 34 so long as the difference between the first axial distance 30 and the second axial distance 34 is accounted for mathematically when calculating the resistance and/or the current.

Furthermore, one of the first axial distance 30 and the second axial distance 34 may also be reduced to zero. It should be appreciated that if the first axial distance 30 is reduced to zero, then the first voltage reading may be taken between the second lead 26 and the third lead 32, and the first portion of the thermocouple reading induced by the temperature of the wire 22 is determined by the thermocouple reading between the first lead 24 and the second lead 26. The first portion of the thermocouple reading is subtracted from the first voltage reading taken between the second lead 26 and the third lead 32 to obtain the second portion of the thermocouple reading induced by the current flowing through the wire, which may be calculated from Equations 1 and 2 above. If the second axial distance 34 is reduced to zero, then the first voltage reading may be taken between the first lead 24 and the second lead 26, and the first portion of the thermocouple reading induced by the temperature of the wire 22 is determined by the thermocouple reading between the second lead 26 and the third lead 32. The first portion of the thermocouple reading is subtracted from the first voltage reading taken between the first lead 24 and the second lead 26 to obtain the second portion of the thermocouple reading induced by the current flowing through the wire, which may be calculated from Equations 1 and 2 above.

The second arrangement of the thermocouple 20 operates similarly to the first arrangement of the thermocouple 20. However, because the second arrangement of the thermocouple 20 includes the third lead 32, measuring the first voltage reading may be further defined as measuring the first voltage reading between the first lead 24 and the second lead 26. Similarly, measuring the second voltage reading may be further defined as measuring the second voltage reading between the second lead 26 and the third lead 32. Accordingly, the second arrangement of the thermocouple 20 does not require reversing the polarity of the current flowing through the wire 22.

Alternatively, it is possible that both the first lead 24 and the second lead 26 are both either positive or negative leads, and the third lead 32 is the other of the positive or negative lead. If this is the case, then the first voltage reading may be measured between the first lead 24 and the third lead 32, and the second voltage reading may be measured between the second lead 26 and the third lead 32. Additionally, if both the first lead 24 and the second lead 26 are both either positive or negative leads, and the third lead 32 is the other of the positive or negative lead, then the mathematic calculations of Equations 1 and 2 may also need to be adjusted. For example, in this situation, the variable L would be the axial distance between the first lead 24 and the third lead 32, i.e., the sum of the first axial distance 30 and the second axial distance 34. One skilled in the art should now appreciate the variations in the mathematic calculations of Equations 1 and 2 required for this situation.

While the best modes for carrying out the invention have been described in detail, those familiar with the art to which this invention relates will recognize various alternative designs and embodiments for practicing the invention within the scope of the appended claims.

1. A method of using a thermocouple to calculate a temperature of a wire and a current flowing through the wire, the thermocouple having at least a first lead coupled to the wire and a second lead coupled to the wire with the second lead axially spaced from the first lead a first axial distance along a longitudinal axis of the wire, the method comprising:
measuring a first voltage reading of the thermocouple with the current at a first polarity;
measuring a second voltage reading of the thermocouple with the same current at a second polarity;
averaging the first voltage reading and the second voltage reading to obtain an average voltage reading;
calculating the temperature of the wire from the average voltage reading;
calculating a difference of the first voltage reading and the second voltage reading to obtain a voltage difference derived from the current flowing through the wire; and
calculating the current flowing through the wire based upon the voltage difference between the first voltage reading and the second voltage reading.

2. A method as set forth in claim 1 further comprising reversing the polarity of the current flowing through the wire from the first polarity to the second polarity.

3. A method as set forth in claim 1 wherein calculating the current flowing through the wire based upon the voltage difference includes solving the equation:
$$I = \frac{V}{R}$$
wherein: I is the current flowing through the wire; V is the voltage induced by the current flowing through the wire over the first axial distance, i.e., the electromotive force due to the presence of the current; and R is the resistance of the wire along the first axial distance.

4. A method as set forth in claim 1 wherein calculating the current flowing through the wire based upon the voltage difference includes referencing a correlation table relating various voltages to known currents of the wire.

5. A method as set forth in claim 1 wherein the first polarity is equal to the second polarity, and wherein the thermocouple includes a third lead with two of the first lead, the second lead and the third lead each being one of a positive lead or a negative lead, and the other of the first lead, the second lead and the third lead being the other of the negative lead or the positive lead, wherein the method further includes attaching the third lead to the wire such that the third lead is spaced axially from the second lead a second axial distance, the second lead is disposed axially between the first lead and the third lead, and the first axial distance is equal to the second axial distance.

6. A method as set forth in claim 5 wherein measuring the first voltage reading is further defined as measuring the first voltage reading between the first lead and the second lead.

7. A method as set forth in claim 6 wherein measuring the second voltage reading is further defined as measuring the second voltage reading between the second lead and the third lead.

8. A method of measuring a temperature of a wire having a current flowing through the wire with a thermocouple having a first lead and a second lead, the method comprising:
attaching the first lead to the wire;
attaching the second lead to the wire;
eliminating an effect of the current flowing through the wire on the temperature of the wire;
obtaining a first voltage of the thermocouple when the effect of the current on the temperature of the wire is eliminated; and
calculating the temperature of the wire from the first voltage obtained.

9. A method as set forth in claim 8 wherein eliminating the effect of the current flowing through the wire includes shutting of the current and obtaining a first voltage includes taking at least one voltage reading over a period of time after the current is shut off and using the at least one voltage reading to obtain the first voltage.

10. A method as set forth in claim 9 wherein the at least one voltage reading is taken over a period of equal or greater than 10 nanoseconds.

11. A method as set forth in claim 9 wherein obtaining a first voltage reading includes extrapolating the first voltage from the at least one voltage reading.

12. A method as set forth in claim 11 wherein the at least one voltage reading is taken over a period of equal or less than 1000 seconds.

13. A method as set forth in claim 8 wherein attaching the second lead to the wire is further defined as attaching the second lead to the wire such that an end of the second lead is laterally spaced from and axially aligned with an end of the first lead along the longitudinal axis such that a first axial distance between the end of the first lead and the end of the second lead is equal to zero to eliminate the effect of the current flowing through the wire.

14. A method as set forth in claim 13 wherein the end of the second lead is laterally spaced form the end of the first lead a distance equal to zero.

15. A method as set forth in claim 13 wherein attaching the first lead to the wire includes forming a bead at an end of the first lead prior to attaching the first lead to the wire.

16. A method of measuring a current in a wire having a current flowing through the wire with a thermocouple having a first lead attached to the wire and a second lead attached to the wire and axially spaced from the first lead along a longitudinal axis of the wire, the method comprising:
measuring a voltage reading of the thermocouple;
determining a temperature of the wire;
subtracting a portion of the voltage reading of the thermocouple induced by the temperature of the wire from the voltage reading of the thermocouple to obtain a portion of the voltage reading of the thermocouple induced by the current flowing through the wire; and
calculating the value of the current flowing through the wire based upon the portion of the voltage reading induced by the current flowing through the wire.

17. A method as set forth in claim 16 further comprising measuring an axial distance between the first lead and the second lead along the longitudinal axis of the wire.

18. A method as set forth in claim 17 wherein calculating the value of the current flowing through the wire based upon the portion of the voltage reading induced by the current flowing through the wire is further defined as calculating the value of the current flowing through the wire based upon the portion of the voltage reading induced by the current flowing through the wire and the measured axial distance between the first lead and the second lead.

19. A method as set forth in claim 16 wherein determining a temperature of the wire includes temporarily interrupting the current in the wire to directly measure the temperature of the wire while the current is interrupted.

20. A method as set forth in claim 16 wherein determining a temperature of the wire includes temporarily interrupting the current in the wire to measure a voltage reading of the thermocouple induced by the heat of the wire.
